(19) United States
(12) Patent Application Publication
(10) Pub. No.: US 2010/0321915 A1
(43) Pub. Date: Dec. 23, 2010

(54) CIRCUIT BOARD ARRANGEMENT

(75) Inventors: Ralf Wendler, Falkensee (DE); Jorg Romahn, Berlin (DE); Annette Bolcke, Berlin (DE)

Correspondence Address: SEED INTELLECTUAL PROPERTY LAW GROUP PLLC, 701 FIFTH AVE, SUITE 5400, SEATTLE, WA, 98104, US

(73) Assignee: CINTERION WIRELESS MODULES GMBH, Munchen (DE)

(21) Appl. No.: 12/740,938

(22) PCT Filed: Nov. 3, 2008
(86) PCT No.: PCT/EP2008/064878

§ 371 Date: Aug. 23, 2010

(30) Foreign Application Priority Data
Nov. 2, 2007 (EP) 07075955.0

(51) Int. Cl. H05K 1/11

(52) U.S. Cl. 361/803

(57) ABSTRACT

An arrangement including a first circuit board having a contact surface for contacting of a connecting element, a second circuit board, and a connecting element. The contact surface has a central contact point and a concentric ring surrounding the central contact point. The connecting element which is electrically contacted at a first side with the second circuit board and which at a second side in opposite relationship to the first side includes a first spring element at least one second spring element. The first spring element is electrically contacted with the central contact point of the first circuit board and the at least one second spring element is electrically contacted with the concentric ring of the first circuit board.

### BACKGROUND

1. Technical Field

The invention concerns an arrangement of at least two circuit boards.

2. Description of the Related Art

Conventional circuit boards are fitted with a large number of electronic components. If an electrical device includes two circuit boards they possibly have to be electrically connected together to be able to perform the overall function of the electrical device.

The electrical connection of two circuit boards, for example high frequency units mounted on circuit boards or a high frequency unit mounted on one circuit board and a control unit mounted on the other circuit board, is effected by a connecting element, for example a plug connector. That connecting element is usually soldered on a circuit board on one side. On the other side the connecting element generally includes spring elements which are pressed against another circuit board for contacting purposes.

There are a large number of different types of connecting elements. Depending on the respective type, shape, size and number of the spring elements, the contact surface of the other circuit board to be contacted has to be geometrically matched to the respective connecting element to ensure that there is reliable contact.

A predetermined shape, size and so forth of a connecting element limits the design configuration of the contact surface of the other circuit board to be contacted.

### BRIEF SUMMARY

At least some embodiments of the present invention provide an arrangement of a first circuit board, a connecting element, and a second circuit board. A large number of connecting elements of different shapes and sizes can be used to ensure reliable contact between the connecting element and the two circuit boards.

In one embodiment, an assembly includes:

a first circuit board having a contact surface for contacting of a connecting element, wherein the contact surface has a central contact point and a concentric ring surrounding the central contact point;

a second circuit board; and

a connecting element which is electrically contacted at a first side with the second circuit board and which at a second side in opposite relationship to the first side includes a first spring element and at least one second spring element, wherein the first spring element is electrically contacted with the central contact point of the first circuit board and the at least one second spring element is electrically contacted with the concentric ring of the first circuit board.

In some embodiments, an arrangement includes a first circuit board, a connecting element, and a second circuit board, in which a multiplicity of connecting elements of differing shape and size can be used and which ensures reliable contacting between the connecting element and the two circuit boards.

An advantageous of at least some embodiments of the invention provides that the connecting element includes the first spring element and two second spring elements. The first spring element is electrically contacted with the central contact point and the two second spring elements are electrically contacted with the concentric ring. In that way connecting elements having three spring elements, wherein the individual spring elements are of a pin form, can be used for the arrangement.

In a further advantageous embodiment, as an alternative to the preceding paragraph, the second spring element concentrically surrounds the first spring element. That configuration means that it is possible to employ coaxial connecting elements which are frequently used to connect components.

The arrangement can also be supplemented by further circuit boards, in which case two circuit boards and a connecting element which connects them together respectively form an arrangement according to at least some embodiments of the invention as discussed herein.

### BRIEF DESCRIPTION OF THE SEVERAL VIEWS OF THE DRAWINGS

Advantages of at least some embodiments of the invention will be apparent from the description hereinafter which in conjunction with the accompanying drawings describes the invention by reference to four embodiments by way of example.

FIG. 1 shows an arrangement having a connecting element with three spring elements,

FIG. 2 shows a first circuit board with a contact surface according to the invention,

FIG. 3 shows an overall view of the arrangement of FIG. 1 and the contact surface of FIG. 2, and

FIG. 4 shows the arrangement of FIG. 3 without the second circuit board but with a connecting element which is an alternative to FIG. 3.

### DETAILED DESCRIPTION

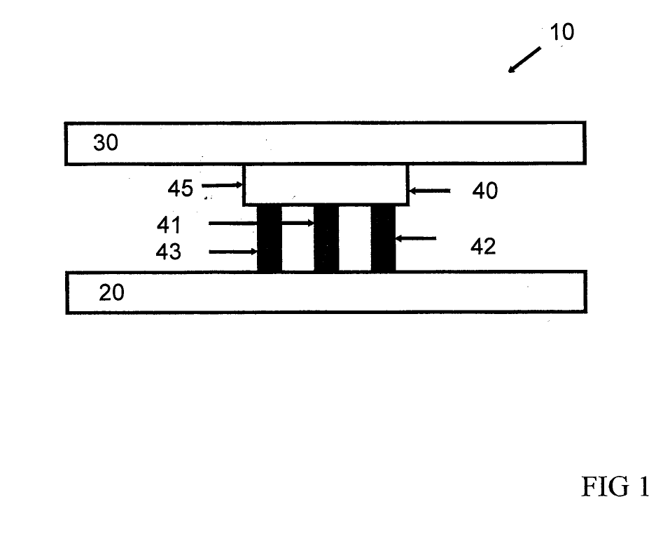

FIG. 1 shows an arrangement 10 including a first circuit board 20, a second circuit board 30 and a connecting element 40 which includes three spring elements 41, 42, 43. The connecting element 40 is electrically contacted with one side, its head 45, to the second circuit board 30. The three spring elements 41, 42, 43 of the connecting element 40 are each of an elongate shape, constituting a so-called pin form. Each of the three spring elements 41, 42, 43 is electrically contacted with the first circuit board 20.

The use of ‘springily resilient’ spring elements 41, 42, 43 is not essential for the invention. The spring elements 41, 42, 43 can be rigid spring elements or connecting projections.

In some embodiments, ‘springily resilient’ spring elements 41, 42, 43 are used because they ensure secure reliable contact between the connecting element 40 and the first circuit board 20, particularly if assembly of a connecting element 40 connected to the second circuit board 30 and a first circuit board 20 is implemented by contact-pressure contact.

‘Springily resilient’ spring elements 41, 42, 43 also ensure secure reliable contact insofar as rotation or displacement between the first and second circuit boards 20, 30 can be better compensated without breaking the contact (for example, by tearing away of the spring elements 41, 42, 43).

In practice, at least some embodiments of the invention may be suitable for high frequency board-to-board circuit boards which are known to one of ordinary skill in the art.

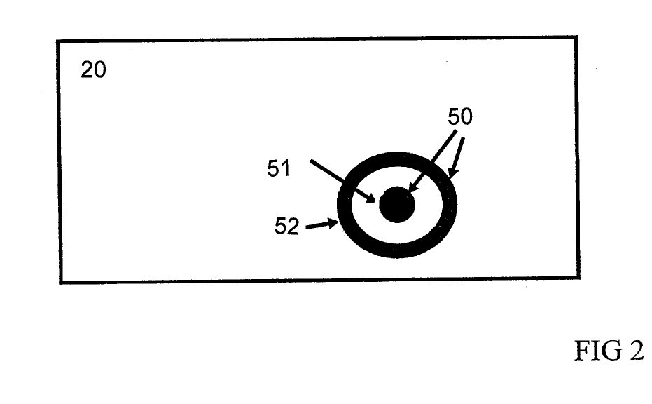

FIG. 2 shows a first circuit board 20 having a contact surface 50 for contacting of the connecting element 40 of FIG. 1. The contact surface 50 includes a central contact point 51 and a concentric ring 52 surrounding that central contact point 51.

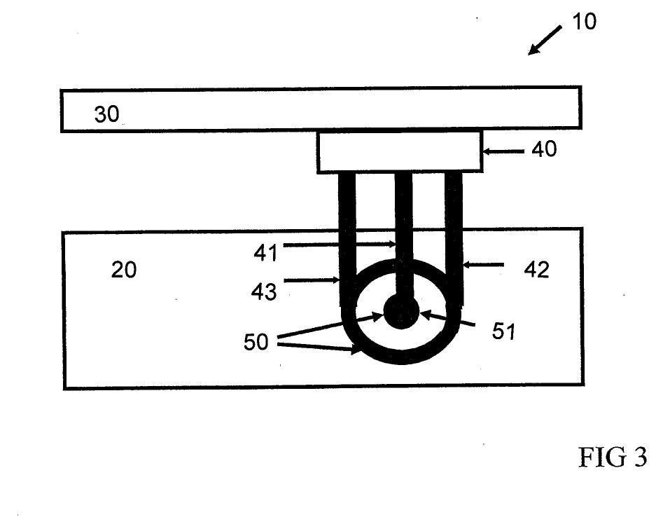

FIG. 3 shows an overall combined view illustrating the arrangement 10 of FIG. 1 and the contact surface 50 of the first circuit board 20 of FIG. 2. The connecting element 40 is electrically contacted at the top side with the second circuit board 30. The three spring elements 41, 42, 43 are disposed at the side in opposite relationship to the first side of the connecting element 40, the underside. The first spring element 41 is electrically contacted with the central contact point 51 of the first circuit board 20. The two second spring elements 42, 43 are electrically contacted with the concentric ring 53 of the first circuit board 20.

It is possible for different types of connecting elements 40 with spring elements 41, 42, 43 in the form of a pin to be used based on the width of the central contact point 51 and the width of the concentric ring 53. At least some embodiments of the invention include an arrangement wherein the connecting element 40 includes only one first spring element 41 and the second spring element 42. That is, the spring element 43 in FIG. 3 can be removed and, thus, would not exist.

What is important for some embodiments of the invention is that, even if the circuit boards 20, 30 (or the connecting element 40 fixedly connected to the second circuit board 30) are to be contacted in mutually rotated relationship (up to 360 degrees), that is readily possible to provide a proper electrical connection by virtue of the shape of the contact surface 50 of the first circuit board 20. As already described the ‘springily resilient’ spring elements 41, 42, 43 compensate for even minor spacing tolerances in the lateral and vertical directions between the circuit boards 20, 30. As in practice generally the shape and size of the connecting element 40 which is fixedly connected to the second circuit board 30 is predetermined, the special geometrical configuration of the contact surface 50 of the first circuit board 20 permits the contacting of various predetermined connecting elements 40 without changing the layout of the first circuit board 20.

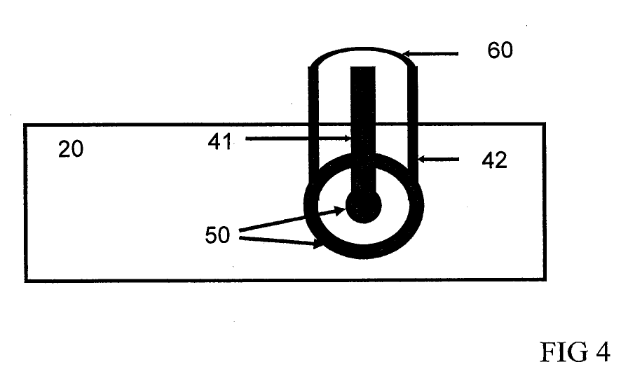

FIG. 4 shows the arrangement of FIG. 3 without the second circuit board 30 but with a connecting element 60 which is an alternative to FIG. 3. On the top side, as described with reference to FIG. 3, the connecting element 60 is connected to the second circuit board (not shown in FIG. 4). To better illustrate the shape of the connecting element 60, the upper part of the connecting element 60 that would contact the second circuit board is not shown.

The connecting element 60 includes two spring elements 41, 42. The first spring element 41 is in the form of a central pin and the second spring element 42 concentrically surrounds the first spring element 41. That type of connecting element 60 is generally referred to as a coaxial connecting element. This also involves the advantages according to at least some embodiments of the invention, that contact between the spring elements 41, 42 and the contact surface 50 is also possible when the second circuit board, which is fixedly connected to the spring elements 41, 42 or to the connecting element 60, respectively, is to be contacted with the first circuit board 20 in rotated relationship. The further considerations described in the foregoing Figures relating to the configuration of the contact surface 50 and the spring elements 41, 42 of FIGS. 1-3 correspondingly apply to the connecting element 60 in FIG. 4.

The invention is not limited to the specific embodiment by way of example but includes further modifications which are not explicitly disclosed insofar as use is made of the core of the invention. That applies in particular if the contact surface does not include an exactly concentric ring but for example an elliptical or polygonal one, in which case nonetheless the effect according to the invention is achieved by virtue of the dimensioning of the width of the spring elements.

1. An assembly comprising:
a first circuit board having a contact surface for contacting of a connecting element, wherein the contact surface has a central contact point and a concentric ring surrounding the central contact point;
a second circuit board; and
a connecting element electrically contacting at a first side with the second circuit board and at a second side in opposite relationship to the first side including a first spring element and at least one second spring element, wherein the first spring element is electrically contacted with the central contact point of the first circuit board and the at least one second spring element is electrically contacted with the concentric ring of the first circuit board.

2. The assembly of claim 1 wherein the at least one second spring element includes two second spring elements electrically contacted with the concentric ring.

3. The assembly of claim 1 in which the second spring element concentrically surrounds the first spring element.

4. An assembly, comprising:
a first circuit board including a central contact region and a ring surrounding the central contact region;
a second circuit board; and
a connecting element having a first end electrically contacting the first circuit board and a second end, the second end including a first spring element and at least one second spring element, the first spring element electrically contacting the central contact region of the first circuit board and the at least one second spring element electrically contacting the ring of the first circuit board.

5. The assembly of claim 4, wherein the first end of the connecting element includes a head electrically contacting the second circuit board, and the first spring element and the second spring element are spaced apart from one another and extend from the head to the first circuit board.

6. The assembly of claim 4, wherein the at least one second spring element comprises a pair of second spring elements electrically contacting the ring.

7. The assembly of claim 6, wherein a distance from the first spring element to one of the second spring elements is substantially equal to a distance from the first spring element to the other second spring element.

8. The assembly of claim 4, wherein the ring is substantially concentric with the central contact region.

9. The assembly of claim 4, wherein the at least one second spring element concentrically surrounds the first spring element.

10. The assembly of claim 4, wherein the at least one second spring element comprises a pair of second spring elements that electrically contact opposing sides of the ring, and the first spring element is between the pair of the second spring elements.

11. The assembly of claim 4, wherein the ring has a substantially circular shape, an elliptical shape, or a polygonal shape.
